(19) United States
(12) Patent Application Publication
(10) Pub. No.: US 2009/0046419 A1
(43) Pub. Date: Feb. 19, 2009

(54) HOT SWAPPABLE HDD TWIN PACK TRAY

(75) Inventors: James R. Drake, Cary, NC (US); James S. Womble, Hillsborough, NC (US)

Correspondence Address: HOFFMAN WARNICK LLC, 75 STATE STREET, 14TH FLOOR, ALBANY, NY, 12207, US

(73) Assignee: International Business Machines Corporation, Armonk, NY (US)

(21) Appl. No.: 11/838,332

(22) Filed: Aug. 14, 2007

(51) Int. Cl. H05K 5/02

(52) U.S. Cl. 361/685

(57) ABSTRACT

Two HDDs are mounted in a single hot swap twin pack tray. The orientation of HDDs—Printed Circuit Boards (PCBs) on HDDs are mounted facing inboard. HDDs operate in opposing directions (counter-rotational) to each other (i.e., so that the platters are spinning in opposite rotational direction, actuator arms are moving in opposite directions, and the motors are operating in opposite directions) providing smoother operation by dampening vibrations by cancelling each other's vibrations. The orientation of HDDs automatically provides protection for PCBs in dense environments.

### FIELD OF THE INVENTION

The present invention relates generally to hard disk drives (HDDs) and, more specifically, to an orientation of multiple HDDs in a system to reduce the vibration and harmonics associated with the spinning of the platters and movement of the actuating arms so that the HDDs can act at high performance and to reduce the risk of damage to PCBs.

### BACKGROUND OF THE INVENTION

An HDD is a hard disk drive, commonly referred to as a hard drive or hard disk, is a non-volatile storage device which stores digitally encoded data on rapidly rotating platters with magnetic surfaces. Strictly speaking, “drive” refers to a device distinct from its medium, such as a tape drive and its tape, or a floppy disk drive and its floppy disk. For more information re HDDs, see http://www.techweb.com/encyclopedia/defineterm.jhtml?term=harddisk.) The rapid spinning of the platters causes vibrations within the system which can lead to vibrations greater than the acceptable range applied to the HDD during operation will be transmitted to the read heads and will degrade read-write performance and can lead to HDD failure/data loss. The problem with the hard drive rotation is that the rotation introduces vibrations/shocks to the system from HDD mechanicals, such as the motor, the spinning of the platters, the movement of the actuator arms, and so forth. Many systems today require multiple HDDs. In the multi-HDD environments present today, (i.e., Servers, Storage Servers, DASD expansion units and others), the HDDs are oriented in the same direction, that is to say, the HDDs spin in the same rotational direction. This merely increases the vibrations/shocks to the system.

Furthermore, harmonic/resonance vibrations are aggravated by multiple drives all operating in the same orientation (that is, platters/motors spinning in the same direction, the actuator arms actuating in same direction and so forth). This can introduce issues with system vibration (such as in the systems/racks/cabinets) as an HDD may be adversely affected by system vibration due to resonance/harmonic vibrations in multi-system environments. This could be most apparent where there is a rack is full of DASD Systems all spinning in the same rotational direction. (A DASD, or direct access storage device, is a form of magnetic disk historically used in the mainframe and minicomputer (mid-range) environments.) If the vibrations can find a resonance, the vibrations can increase in the systems/rack with the other spinning disks.

The problem with vibrations is that vibrations from other HDDs greater than an acceptable range applied to an HDD during operation will be transmitted to the read heads and will degrade read-write performance and can lead to HDD failure/data loss.

Utilizing present systems, migration of systems to mount Hard Disk Drives in denser environments cause issues as well. As a result of dense environments, HDDs are more susceptible to damage from adjoining drives and sheet metal features, or, alternatively, coming in contact with a printed circuit board (PCB) during a plug/unplug operation.

Present systems utilize hot swap trays and their mounting environments incorporate vibration solutions into their designs to reduce HDD vibrations, that is, they utilize vibration springs, dampening springs/pads, or other special materials (such as laminated “deadening” steel, and various other mechanical design considerations to reduce rotational/harmonics/resonance vibrations). With regard to hot swapping, “hot swapping” or “hot plugging” is the ability to remove and replace components of a machine, usually a computer, while it is operating. Once the appropriate software is installed on the computer, a user can plug and unplug the component without rebooting. One of the problems with hot swapping HDDs is that PCBs, located nearby in dense environments, may be damaged during the hot-swap operation. (A PCB, or printed circuit board, is used to mechanically support and electrically connect electronic components using conductive pathways, or traces, etched from copper sheets laminated onto a non-conductive substrate. See http://www.dscc.dla.mil/Programs/MilSpec/listdocs.asp?BasicDoc=MIL-PRF-31032.)

In some dense environments, protective covers have been introduced to the PCB side of the HDD hot swap carrier to provide protection from damage. The current solutions introduce additional costs (i.e., laminated steel construction of HDD cage areas) to the product and introduce exposures to the product (i.e., thermal concerns with the protective cover).

There presently is a need for a system for hot swapping HDDs in a new twin pack tray.

### BRIEF SUMMARY OF THE INVENTION

The present invention is a system for a new orientation of multiple HDDs to reduce vibration and harmonics so that the HDDs can act at high performance and to reduce the risk of damage to PCBs and for hot swapping HDDs in a new twin tray pack.

Two HDDs are mounted in a single hot swap twin pack tray. The orientation of HDDs—Printed Circuit Boards (PCBs) on HDDs are mounted facing inboard. HDDs operate in opposing directions (counter-rotational) to each other (i.e., so that the platters are spinning in opposite rotational direction, actuator arms are moving in opposite directions, and the motors are operating in opposite directions) providing smoother operation by dampening vibrations by cancelling each other's vibrations. The orientation of HDDs automatically provides protection for PCBs in dense environments.

The illustrative aspects of the present invention are designed to solve one or more of the problems herein described and/or one or more other problems not discussed.

### BRIEF DESCRIPTION OF THE SEVERAL VIEWS OF THE DRAWINGS

These and other features of the invention will be more readily understood from the following detailed description of the various aspects of the invention taken in conjunction with the accompanying drawings that depict various embodiments of the invention, in which:

FIG. 1 depicts the hot swap HDD twin pack tray of the present invention.

FIG. 2 shows the left and right hand sides of the tray and the HDDs mounted in the tray of the present invention.

FIG. 3 illustrates the HDDs mounted within the tray of the present invention.

The drawings are intended to depict only typical aspects of the invention, and therefore should not be considered as limiting the scope of the invention. In the drawings, like numbering represent like elements between the drawings.

### DETAILED DESCRIPTION OF THE PREFERRED EMBODIMENT OF THE PRESENT INVENTION

The present invention provides a system for an orientation of multiple HDDs to reduce vibration and harmonics so that the HDDs can act at high performance and to reduce the risk of damage to PCBs.

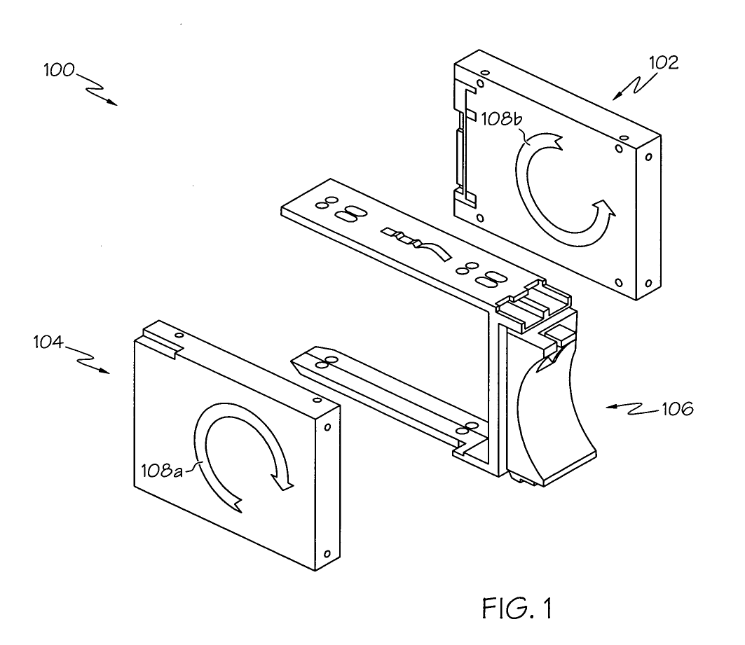

FIG. 1 depicts a System 100 wherein two HDDs 102, 104 are mounted in the single hot swap twin pack tray 106 of the present invention. The orientation of HDDs 102, 104—or Printed Circuit Boards (PCBs) on HDDs are mounted facing inboard. HDDs 102, 104 operate in opposing directions 108a, 108b (counter-rotational) to each other, (i.e., the rotation of the platters, the movement of the actuator arms, and the spinning of motors) providing smoother operation by dampening vibrations. The orientation of HDDs automatically provides protection for PCBs in dense environments.

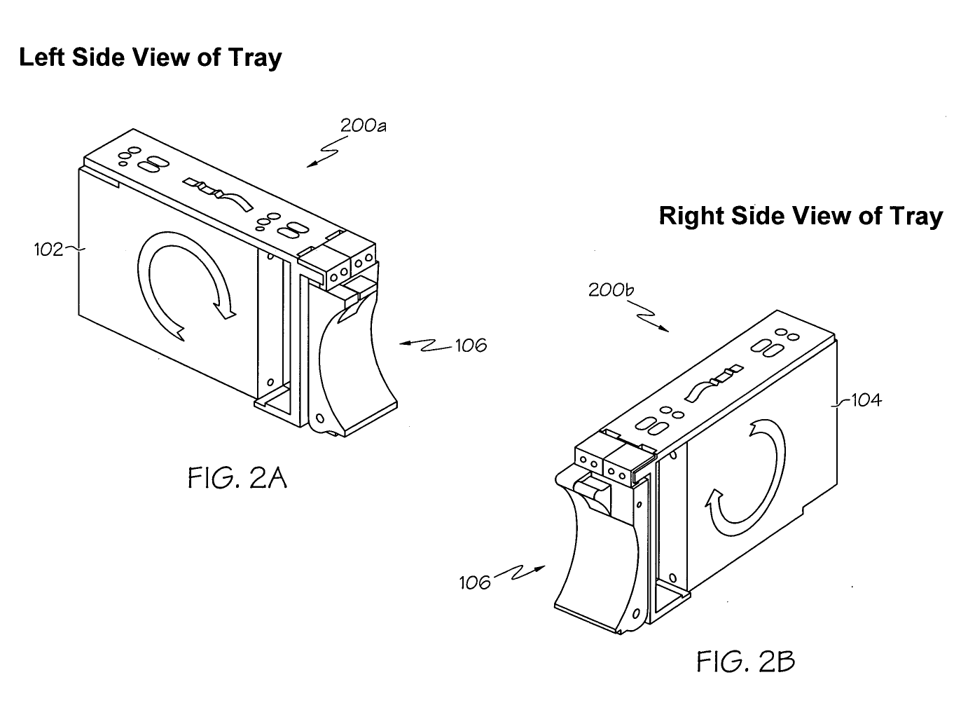

FIG. 2 illustrates a left side view 200 a and a right side view 200b of the HDDs mounted in the tray of the present invention. As can be seen, HDDs 102, 104 are inserted in Tray 106 and are inserted in Tray 106 such that the HDDs are spinning in counter-rotational directions as noted by the arrows. Because of the counter-rotational of the spinning platters as well the opposite movement of the arms, the vibration is reduced and there is low likelihood for a resonant frequency to causes vibration or movement issues.

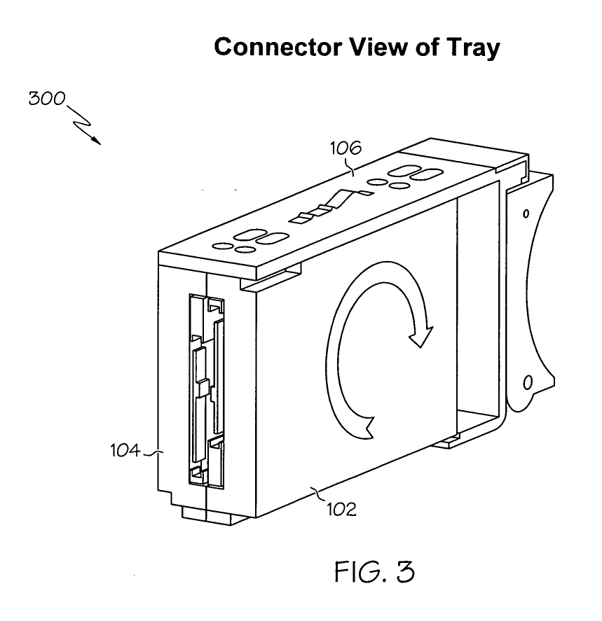

FIG. 3 shows the HDDs mounted within the tray of the present invention and illustrating that the rational spins of the HDDs are counter-rotational so that the vibrations and other issues are dampened. The Tray 106, while dampening the vibrations, further allows for the hot-swapping of the HDDs. Hot-swapping can be risky in that, because the power is on, in a densely populated system, boards can touch features of the enclosure or adjacent HDD trays and cause a short circuit/damage to the HDD PCB. The Tray 106 of the present invention, because of the HDD orientation with the PCB's inboard, allows the HDDs to be hot-swapped without risk of shorting/damaging PCB local boards.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. A system for reducing the vibrations caused by the spinning of the hard disk drives (HDDs) in a computer system, the system comprising:
a. a single twin pack tray for receiving a first and a second HDD;
b. a first HDD having a first spin rotational direction mounted in one side of the hot swap twin pack tray;
c. a second HDD having a second spin rotational direction mounted in anther side of the twin pack tray;
wherein the first HDD is oriented such that the first spin rotational direction is opposite from the second rotational direction when first HDD and second HDD are mounted in the twin pack tray for protection of other circuit boards in a dense hot swapping environment

2. The system of claim 1 wherein the first and second HDDs are mounted on printed circuit boards (PCBs) and are mounted facing inboard.

3. The system of claim 1 wherein the first HDD is positioned such that there is a gap between the second HDD so that air flow can occur between the first HDD and the second HDD and adequate cooling can occur.

4. The system of claim 1 wherein the twin pack tray is a hot swap twin pack tray.

5. The system of claim 4 wherein the hot swap twin pack tray accepts the first HDD and a second HDD in positions such that the spinning of the first HDD is counter-rotational to the second HDD.

6. The system of claim 5 wherein the HDDs are hot swappable so that the HDDs may be swapped or hot unplugged or removed and replaced as necessary without rebooting.

7. A tray for receiving a first hard disk drive (HDD) and a second HDD comprising:
a. a first slot for receiving the first HDD which spins in a first rotational direction; and
b. a second slot for receiving the second HDD which spins in a second rotational direction, the second slot for receiving the second HDD so that the second HDD is spinning in an opposite rotational direction from the first HDD.

8. The tray of claim 7 wherein the HDDs are hot-swappable.
